(19) United States
(12) Patent Application Publication
(10) Pub. No.: US 2025/0015783 A1
(43) Pub. Date: Jan. 9, 2025

(54) HYBRID BANDPASS FILTER HAVING ACOUSTIC WAVE AND ELECTROMAGNETIC RESONATORS

(71) Applicant: TEXAS INSTRUMENTS INCORPORATED, Dallas, TX (US)

(72) Inventors: Gokhan Ariturk, Norman, OK (US); Adam Fruehling, Dallas, TX (US); Yao Yu, San Jose, CA (US); Ting-Ta Yen, San Jose, CA (US)

(21) Appl. No.: 18/349,020

(22) Filed: Jul. 7, 2023

(51) Int. Cl. H03H 9/56; H03H 9/54

(52) U.S. Cl. CPC H03H 9/568; H03H 9/542

(57) ABSTRACT

A filter includes an electromagnetic (EM) resonator having a first EM resonator terminal and a second EM resonator terminal. The second EM filter terminal is coupled to a ground terminal. The filter includes a first bulk acoustic wave (BAW) resonator coupled between the first EM resonator terminal and the ground terminal and includes a second BAW resonator coupled between the first EM resonator terminal and the ground terminal. A third BAW resonator is coupled between a first filter terminal and a first BAW resonator terminal of the first BAW resonator. A fourth BAW resonator is coupled between a second filter terminal and a second BAW resonator terminal of the second BAW resonator.

### BACKGROUND

A bandpass filter can pass a signal within a pass band and attenuate another signal in the stop band above and below the pass band. The frequency range of the pass band can be defined by an upper corner frequency and a lower corner frequency, with a center frequency in the middle of the pass band. A fractional bandwidth of the bandpass filter can be defined by the ratio between the width of the pass band and the center frequency.

A bandpass filter has transition bands between the pass band and the stop bands above and below the pass band. Within each transition band, the frequency response rolls off from the pass band to the respective stop band. It is desirable for a bandpass filter to have narrow transition bands and sharp roll off, as well as high attenuation/rejection outside the pass band, to increase selectivity of the filter. Also, some applications, such as applications that operate on millimeter waves (mmWave) where the frequency is between 30-300 Gigahertz (GHz), may benefit from a large fractional bandwidth.

### SUMMARY

In an example, a filter includes an electromagnetic (EM) resonator having a first EM resonator terminal and a second EM resonator terminal. The second EM filter terminal is coupled to a ground terminal. The filter includes a first bulk acoustic wave (BAW) resonator coupled between the first EM resonator terminal and the ground terminal and includes a second BAW resonator coupled between the first EM resonator terminal and the ground terminal. A third BAW resonator is coupled between a first filter terminal and a first BAW resonator terminal of the first BAW resonator. A fourth BAW resonator is coupled between a second filter terminal and a second BAW resonator terminal of the second BAW resonator.

In another example, a filter comprises a first acoustic wave (AW) resonator, a second AW resonator, a third AW resonator, a fourth AW resonator, and an electromagnetic (EM) resonator network coupled between a first filter terminal and a second filter terminal. The filter further comprises a feedforward circuit coupled between the first filter terminal and the second filter terminal.

### BRIEF DESCRIPTION OF THE DRAWINGS

FIG. 1 is a diagram of a communication device that implements two or more wireless protocols using a bandpass filter in accordance with various examples.

FIGS. 2A, 2B, and 2C are schematic diagrams of an example hybrid bandpass filter including acoustic wave (AW) resonators and an electromagnetic (EM) resonator in accordance with various examples.

FIG. 3 is a cross-sectional view of an acoustic wave (AW) resonator in accordance with various examples.

FIG. 4 is an electrical model of an AW resonator in accordance with various examples.

FIG. 5 is an admittance graph of the AW resonator model of FIG. 4 in accordance with various examples.

FIG. 6 is an electrical model of an EM resonator in accordance with various examples.

FIG. 7 is an impedance versus frequency graph for an EM resonator in accordance with various examples.

FIG. 8 is a graph illustrating impedances and combined frequency responses of AW resonators of the filter of FIG. 2, in accordance with various examples.

FIG. 9 is a graph illustrating frequency responses of filters having different fractional bandwidths, in accordance with various examples.

FIG. 10 is a graph illustrating a technique of improving pass band transmission coefficient of a filter, in accordance with various examples.

FIG. 11 is a graph illustrating improvement of pass band transmission coefficient of a filter by EM resonator, in accordance with various examples.

FIG. 12 is a graph illustrating improvement of pass band transmission coefficient by EM resonator for filters of different fractional bandwidth, in accordance with various examples.

FIG. 13 is a schematic diagram of a bandpass filter having a feedforward circuit, in accordance with various examples.

FIG. 14 is a graph illustrating improvement of fractional bandwidth enabled by the feedforward circuit of FIG. 13, in accordance with various examples.

FIG. 15 is a schematic diagram of another bandpass filter having a feedforward circuit, in accordance with various examples.

FIGS. 16-19 are schematic diagrams of a feedforward circuit in accordance with various examples.

### DETAILED DESCRIPTION

The same reference numbers or other reference designators are used in the drawings to designate the same or similar (either by function and/or structure) features.

A bandpass filter can be implemented using acoustic wave (AW) resonators, such as bulk acoustic wave (BAW) resonators or surface acoustic wave (SAW) resonators. The AW resonators may be coupled together in a ladder topology with at least one AW resonator being coupled in series along the signal path and at least one resonator being a shunt resonator coupled to ground. While the use of AW resonators is advantageous due to their relatively high quality factor (Q factor) in a relatively small volume, a bandpass filter comprising only AW resonators may have a limited achievable fractional bandwidth and limited out-of-band rejection. As to be described below, the limited fractional bandwidth and limited out-of-band rejection can be due to various properties of an AW resonator, such as the presence of parallel and series resonances which can cause attenuation in the pass band, as well as limit on fractional bandwidth and out-of-band rejection imposed by electromechanical coupling coefficients kₜ² of the AW resonators.

The examples described herein pertain to a hybrid bandpass filter that includes resonators of different types, including AW resonators and electromagnetic (EM) resonators. The EM resonators can be implemented in various forms, such as cavity resonators, dielectric resonators, transmission line resonators, or lumped element resonators. The hybrid filter includes both AW and EM resonators arranged in a ladder topology. In some examples, the hybrid filter can include one or more EM resonators in the middle of the ladder, first AW resonators coupled between the input (or a first filter terminal) and the EM resonator, and second AW resonators coupled between the output (or a second filter terminal) and the EM resonator. As described below, the inclusion of the one or more EM resonators can reduce the attenuation in the pass band, improve out-of-band rejection, and increase the fractional bandwidth. The inclusion of the one or more EM resonators may also reduce the electromechanical coupling coefficients kₜ² of the AW resonators needed to achieve a particular out-of-band rejection and fractional bandwidth. In some examples, a bandpass filter may also include a feedforward circuit coupled between the input and output of the filter to introduce additional transmission zeros, which allows further improvement of fractional bandwidth while providing the same or improved out-of-band rejection, or reduction of the kₜ² of the AW resonators. As to be explained below, a large fractional bandwidth may be advantageous for certain applications, such as C-band, X-band, and mmWave applications. Also, the kₜ² of an AW resonator may depend on the resonator material. Having a reduced kₜ² requirement allows all the AW resonators of the hybrid filter to be fabricated using a same and known resonator material, which can facilitate fabrication and integration of the AW resonators in the band pass filter while providing improved pass band property, out-of-band rejection, and fractional bandwidth.

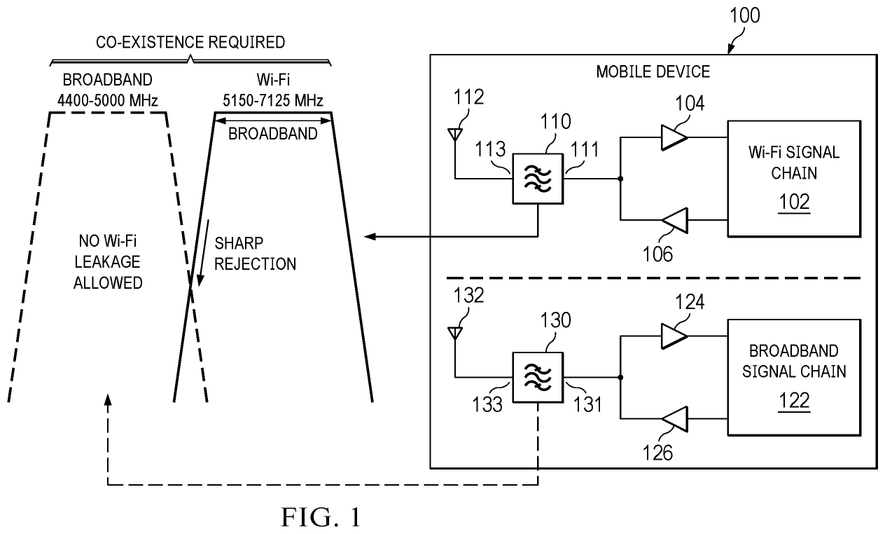

FIG. 1 is a diagram of a device 100 in which one or more hybrid filters as described herein can be used. The hybrid filters can be used in other types of devices and systems as well. In the example of FIG. 49ok1, device 100 includes a mobile device (e.g., cellular phone, tablet device, etc.). Device 100 is capable of wireless communications in accordance with two or more wireless communication protocols. For example, device 100 can implement a Wi-Fi wireless communication protocol (e.g., Wi-Fi 6) and a broadband cellular communication protocol (e.g., 5G New Radio (5G NR)). For Wi-Fi wireless communications, device 100 includes a Wi-Fi signal chain circuit 102, buffers 104 and 106, a bandpass filter 110, and an antenna 112. The Wi-Fi signal chain circuit 102 can be coupled to an input of buffer 106, and the output of buffer 106 can be coupled to a filter terminal 111 of filter 110. Antenna 112 is coupled to a filter terminal 113 of filter 110. Filter terminal 111 is coupled to an input of buffer 104, and an output of buffer 104 is coupled to the Wi-Fi signal chain circuit 102. Device 100 can transmit Wi-Fi wireless signals through antenna 112 and receive wireless signals from antenna 112 to support bidirectional communications. Bandpass filter 110 thus can filter signals in either direction-signals flowing from filter terminal 113 through filter 110 to filter terminal 111 or signals flowing from filter terminal 111 through filter 110 to filter terminal 113.

Device 100 also includes circuitry to support broadband cellular communication. For example, device 100 includes a broadband cellular signal chain circuit 122, buffers 124 and 126, a bandpass filter 130, and an antenna 132. The broadband cellular signal chain circuit 122 can be coupled to an input of buffer 126, and the output of buffer 126 can be coupled to a filter terminal 131 of filter 110. Antenna 132 is coupled to a filter terminal 133 of filter 130. Filter terminal 131 is coupled to an input of buffer 124, and an output of buffer 124 is coupled to the broadband signal chain circuit 122. Device 100 can transmit broadband wireless signals through antenna 132 and receive wireless signals from antenna 132 to support bidirectional communications. Bandpass filter 130 thus can filter signals in either direction-signals flowing from filter terminal 133 through filter 130 to filter terminal 131 or signals flowing from filter terminal 131 through filter 130 to filter terminal 133.

The bandpass filters 110 and 130 can support co-existence of Wi-Fi 6 and 5G NR, where device 100 can support 5G NR cellular communication (using broadband cellular signal chain 122) in the presence of Wi-Fi 6 signals, and support Wi-Fi 6 communication (using Wi-Fi signal chain 102) can support Wi-Fi 6 communication in the presence of 5G NR signal. Specifically, bandpass filter 110 can perform bandpass filtering on the signal received/transmitted by antenna 112, so that the filtered signal at antenna 112 is within the Wi-Fi 6 frequency band. Also, bandpass filter 130 can perform bandpass filtering on the signal received/transmitted by antenna 132, so that the filtered signal at antenna 132 is within the 5G NR frequency band.

Either or both bandpass filters 110 and 130 can be implemented as any of the example hybrid band filters described herein. FIG. 1 includes example frequency spectra for the device's Wi-Fi and broadband communications. In this example, the frequency range of Wi-Fi 6 signals can be between 5150 to 7125 MHZ (5.15 to 7.125 GHZ), and the 5G NR signals can have the n79 frequency band in the range of 4400 to 5000 MHZ (4.4 to 5 GHZ). Both Wi-Fi 6 and 5G NR signals are mmWave signals. Because the upper end of the n79 frequency range (5000 MHZ) is close to the lower end of the Wi-Fi 6 frequency range (5150 MHZ), each of bandpass filters 110 and 130 can have sharp roll offs, and strong out-of-band rejection, to reduce signal leakage and/or interference between the Wi-Fi signals and 5G NR signals at Wi-Fi signal chain 102 and broadband cellular signal chain 122 near the upper end of the n79 frequency range and the lower end of the Wi-Fi 6 frequency range. Also, both filters 110 and 130 can have relatively high fractional bandwidths (e.g., around 20% for Wi-Fi 6, around 30% for 5G NR) to be able to pass signals within the respective Wi-Fi 6 and 5G NR frequency ranges with minimum attenuation. The hybrid bandpass filters described herein can implement fairly large fractional bandwidths with sharp roll-offs on either or both sides of the pass-band (large out-of-band rejection), which can be beneficial for a multi-wireless protocol communication device such as device 100 in FIG. 1.

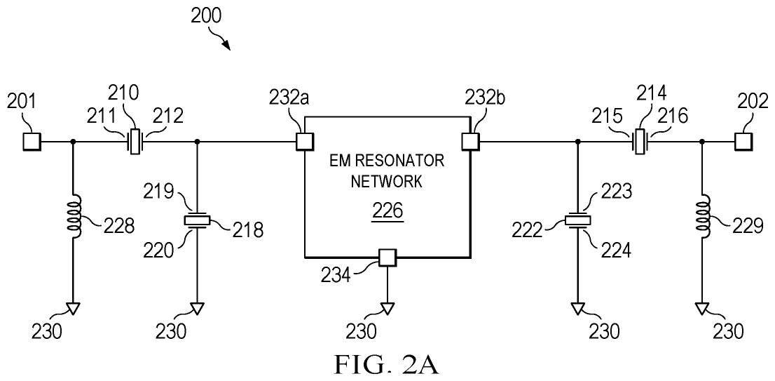

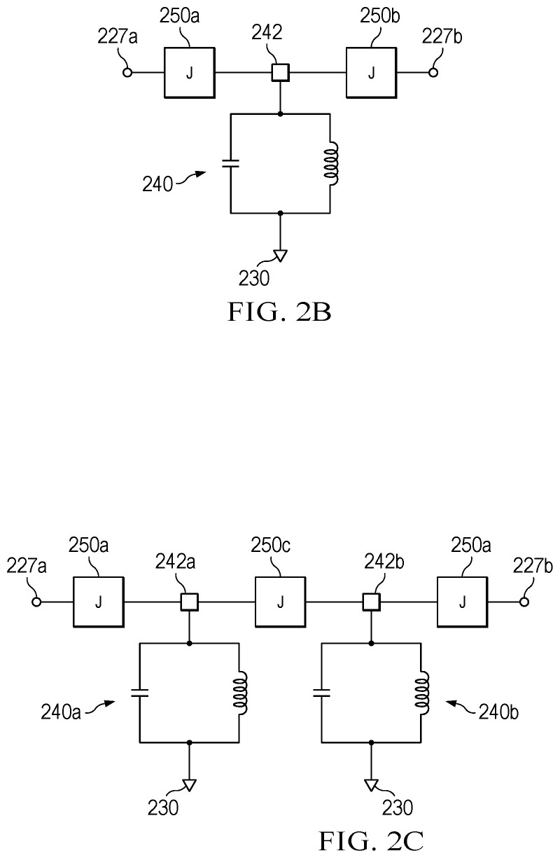

To sharpen the roll-off and improve selectivity, each of bandpass filters 110 and 130 can include a high-order (n^{th} order) bandpass filter, where n is an integer that can be greater than or equal to 3. FIG. 2A is a schematic diagram of a bandpass filter 200 in accordance with an example. Bandpass filter 200 can be used to implement either or both of filters 110 and 130 in FIG. 1. Filter 200 can have a ladder configuration that includes four AW resonators 210, 214, 218, and 222 and an EM resonator network 226. The AW resonators 210, 214, 218, and 222 and EM resonator network 226 are coupled between filter terminals 201 and 202 of filter 200. Filter terminal 201 can correspond to terminals 111 and 131 of filters 110 and 130 (FIG. 1), and filter terminal 202 can correspond to terminals 113 and 133 of filters 110 and 130. In some examples, bandpass filter 200 also includes an inductor 228 coupled between filter terminal 201 and a ground terminal 230, and an inductor 229 coupled between filter terminal 202 and ground terminal 230. In some examples inductors 228/229 can be omitted or be represented by parasitic inductance at respectively filter terminals 201 and 202 (e.g., parasitic inductance of interconnects forming filter terminals 201 and 202). In other examples, capacitors can be included instead of inductors 228 and 229.

In some examples, the AW resonators are bulk acoustic wave (BAW) resonators implemented on a BAW die, and the EM resonator network can also be implemented on the BAW die, so that filter 200 can be implemented on a single die. In some examples, the AW resonators and the EM resonator network can be implemented on different dies.

AW resonator 210 has terminals 211 and 212. AW resonator 214 has terminals 215 and 216. AW resonator 218 has terminals 219 and 220. AW resonator 222 has terminals 223 and 224. EM resonator network 226 includes terminals 232a, 232b and 234. Terminal 211 of AW resonator 210 can be coupled to filter terminal 201, and terminal 216 of AW resonator 214 can be coupled to filter terminal 202. Terminal 212 of AW resonator 210 can be coupled to terminal 219 of AW resonator 218 and to terminal 232a of EM resonator network 226. Also, terminal 215 of AW resonator 214 can be coupled to terminal 223 of AW resonator 222 and to terminal 232b of EM resonator network 226. Terminals 220 and 224 of, respectively, AW resonators 218 and 222, can be coupled to ground terminal 230. Accordingly, AW resonators 210 and are coupled in series between filter terminals 201 and 202 and thus are configured as series AW resonators. AW resonators 218 and 222 are coupled to ground and are configured as shunt AW resonators.

FIGS. 2B and 2C illustrate examples of internal components of EM resonator network 226. Referring to FIG. 2B, EM resonator network 226 can include a single shunt EM resonator 240 represented by a parallel inductor-capacitor (LC) network coupled between an EM resonator terminal 242 and ground terminal 230. EM resonator 240 can include a cavity resonator, a dielectric resonator, a transmission line resonator, or a lumped element resonator. With the EM resonator network 226 of FIG. 2B, filter 200 can be a fifth order bandpass filter. In the example of FIG. 2B, EM resonator network 226 can also include an admittance inverter 250a coupled between terminal 227a and EM resonator terminal 242 and an admittance inverter 250b coupled between EM resonator terminal 242 and terminal 227b. The admittance inverter (e.g., a quarter wavelength transmission line) can convert the admittance of the shunt EM resonator 240 at into the equivalent admittance/impedance of a series EM resonator. The admittance inverter allows a series EM resonator to be implemented using a shunt EM resonator, which may be easier to implement than a series EM resonator.

FIG. 2C illustrates another example of EM resonator network 226. Referring to FIG. 2C, EM resonator network 226 can include two EM resonators 240a and 240b each can be represented by a parallel LC network. EM resonator 240a is coupled between EM resonator terminal 242a and ground terminal 230, and EM resonator 240b is coupled between EM resonator terminal 242b and ground terminal 230. With the EM resonator network 226 of FIG. 2c, filter 200 can be a sixth order bandpass filter. The example of FIG. 2C also includes admittance inverter 250a coupled between filter terminal 227a and resonator terminal 242a, admittance inverter 250b coupled between resonator terminals 242a and 242b, and an admittance inverter 250c coupled between resonator terminal 242b and filter terminal 227b.

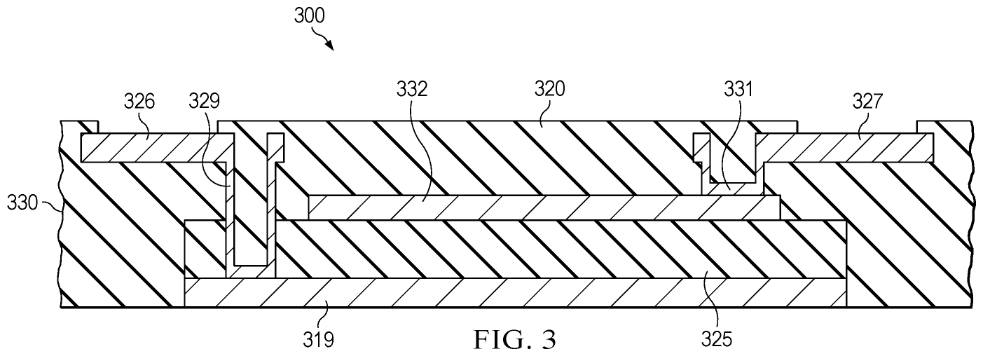

FIG. 3 is a cross-sectional view of an example AW resonator 300, which can be used to implement AW resonators 210, 214, 218, and 222 of FIG. 2 or any other AW resonator described herein. The example AW resonator 300 of FIG. 3 includes an electrode 319, an electrode 332, and a piezoelectric material 325 between electrodes 319 and 332. AW resonator 300 further includes electrical contact 326 electrically coupled to electrode 319 and electrical contact 327 electrically coupled to electrode 332. The size and mass of piezoelectric material 325 can define the resonant frequencies and quality factor of AW resonator 300. Examples of piezoelectric material 325 can include Aluminum Nitride (AlN), Zinc Oxide (ZnO), and Cadmium sulfide (CdS). In some examples, AW resonator 300 can be a bulk acoustic wave (BAW) resonator implemented on a BAW die.

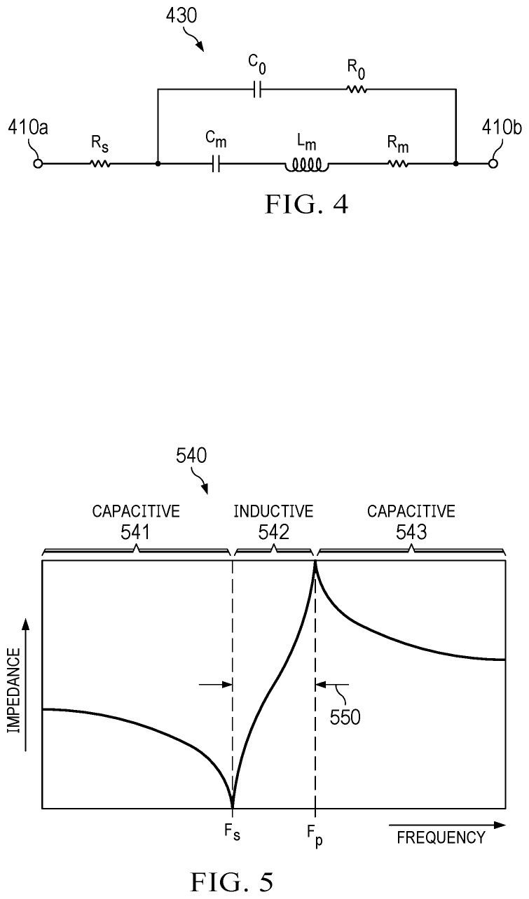

FIG. 4 is an electrical model 430 of an AW resonator (e.g., AW resonator 300) with an alternating current (AC) voltage source coupled across electrical contacts 326 and 327 (and electrodes 319 and 332). The model 430 includes a series resonant component and a parallel resonant component between the resonator terminals 410a and 410b representing, respectively, electrodes 319 and 332. The series resonant component includes a piezoelectric capacitor Cₘ, a piezoelectric inductor Lₘ, and a resistor Rₘ. Piezoelectric capacitor Cₘ is motional capacitance, which is inversely proportional to the stiffness of the piezoelectric layer. Piezoelectric inductor Lₘ is motional inductance which represents the mass of the piezoelectric film. Resistor Rₘ is the motional resistance which represents the damping of the piezoelectric film's vibration. The parallel resonant component includes a parasitic parallel plate capacitor C₀, resistor R₀ (which is the parasitic resistance of the parasitic parallel plate capacitor C₀), resistor Rₘ, the piezoelectric inductor Lₘ, and the piezoelectric capacitor Cₘ. Resistor Rₛ is coupled between terminal 410a and capacitors Cₘ and C₀, and represents resistance of metal routing, electrodes, etc.

FIG. 5 is a graph 540 representing an example variation of impedance of the resonator with frequency of the model 430. Graph 540 for the AW resonator shows a series resonance path having a series resonant frequency Fₛ and a parallel resonance loop having a parallel resonant frequency Fₚ. Both Fₛ and Fₚ can be approximately equal to a frequency of an acoustic signal that resonates in the AW resonator. At such a frequency, the thickness of the piezoelectric material 325 equals half of the acoustic wavelength of the acoustic signal. Accordingly, the Fₛ and Fₚ can be set based on the thickness of piezoelectric material 325 and the material property of piezoelectric material 325 that affects the velocity of propagation of the acoustic signal, which relates between the frequency and wavelength of the acoustic signal.

The series resonance path provides a path in which the impedance of the resonator quickly decreases to a small minimum resonance value (Rₘ) at the resonant frequency Fₛ at which the piezoelectric capacitor Cₘ and the piezoelectric inductor Lₘ cancel. At frequency Fₛ, a low impedance path is created between terminals 410a and 410b of the resonator. At frequencies significantly lower than the series resonant frequency Fₛ (region 541 in FIG. 5), the impedance of piezoelectric inductor Lₘ is nearly a short, and thus the impedance of the resonator is dominated by the parallel combination of capacitors Cₘ and C₀. At frequencies below Fₛ, the AW resonator has a capacitive impedance and, to a first approximation, can be modeled as a capacitor between resonator terminals 410a and 410b. At frequencies significantly higher than the parallel resonant frequency Fₚ (in frequency region 543 in FIG. 5), the impedance of inductor Lₘ increases significantly resulting in the impedance of the AW resonator being dominated by the parasitic parallel plate capacitor C₀, and the resonator's impedance thus is also largely capacitive at such frequencies.

For frequencies at the parallel resonance (Fₚ), current travels around the loop instead of being transmitted from terminal 410a, through the resonator, and out terminal 410b, and so the resonator becomes an open circuit and has a high impedance at the parallel resonance frequency Fₚ. Also, between the series resonant frequency Fₛ and the parallel resonant frequency Fₚ, the resonator's impedance is dominated by inductor Lₘ, and the impedance of the resonator is also inductive.

As to be described below in FIG. 8, when used as a series resonator of a bandpass filter (e.g., series AW resonators 210 and 214 of filter 200 of FIG. 2), resonator 300 can provide a transmission zero at Fₛ where the shunt resonator shorts the input and/or output of the filter to ground, and the Fₚ of the resonator can set a lower pole frequency, which also sets the lower corner frequency of the pass band. Also, when used as a shunt resonator of the bandpass filter (e.g., shunt AW resonators 218 and 222 of filter 200 of FIG. 2), resonator 300 can provide a transmission zero at Fₚ where the series resonator provides a huge impedance and disconnects the filter input from the filter output, and the Fₛ of the resonator can set a higher pole frequency, which also sets the upper corner frequency of the pass band. The impedance of the shunt and series resonators between Fₛ and Fₚ (within frequency range 550) can set the response of the filter within the pass band.

The ratio between the series resonant frequency Fₛ and the parallel resonant frequency Fₚ can determine the electromechanical coupling coefficient kₜ² of the AW resonator, as follows:

$${k}_{t}^{2} = \frac{π}{2} * \frac{{F}_{s}}{{F}_{p}} cot ( \frac{π}{2} \frac{{F}_{s}}{{F}_{p}} ) \qquad ( Equation 1 )$$

In Equation 1, cot is cotangent. A larger ratio between Fₛ and Fₚ (or a larger frequency range 550 between Fₛ and Fₚ) can lead to a larger kₜ², and a smaller ratio between Fₛ and Fₚ can lead to a smaller kₜ². The electromechanical coupling coefficient for an AW resonator is, at least in part, based on the process and materials used to fabricate the AW resonator. The following table provides examples of kₜ² for different piezoelectric materials 325:

TABLE 1

| Material | kₜ² |
|---|---|
| Aluminum Nitride (AlN) | ~6.1-15% |
| Zinc Oxide (ZnO) | ~9.1% |
| Cadmium sulfide (CdS) | ~2.4% |

Table 1 shows that with common piezoelectric materials, such as AlN, ZnO, and CdS, the maximum kₜ² is 15%. Given that kₜ² is fundamentally determined by the material's piezoelectric constant, and it may be impractical to achieve a kₜ² higher than 15% with common (or known) piezoelectric materials such as AlN, ZnO, and CdS. Also, to facilitate fabrication and integration of AW resonators in a filter ladder, the AW resonators of the filter ladder may use the same piezoelectric material and have the same kₜ².

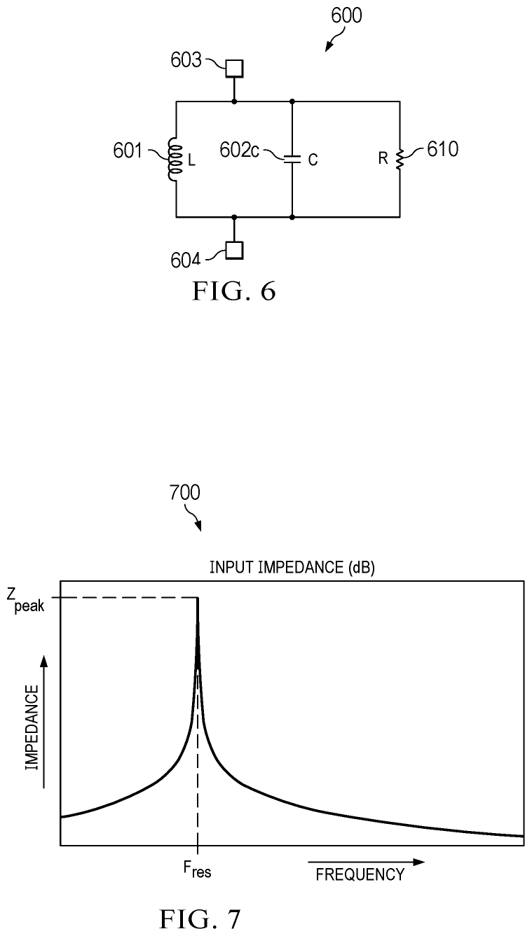

FIG. 6 is an electrical model 600 of an EM resonator, which may represent any of the EM resonators described herein. As described in FIGS. 2B and 2C, an EM resonator may include a parallel LC network including an inductor 601 (having an inductance L) and a capacitor 602 (having a capacitance C) between EM resonator terminals 603 and 604. EM resonator terminal 604 can correspond to EM resonator terminal 242 of FIGS. 2B and 2C, and EM resonator terminal 606 can correspond to the terminal coupled to ground terminal 230 in FIGS. 2B and 2C. The angular resonant frequency (units of radians per second) is

$$\frac{1}{\sqrt{LC}} ,$$

and the equivalent frequency in units of hertz is

$$\frac{1}{2 π \sqrt{LC}} .$$

Also, the EM resonator may include a resistor 610 having a resistance R. Resistor 610 may be parasitic DC resistance of inductor 601 and/or capacitor 602, and may set the quality factor (Q factor) of the EM resonator.

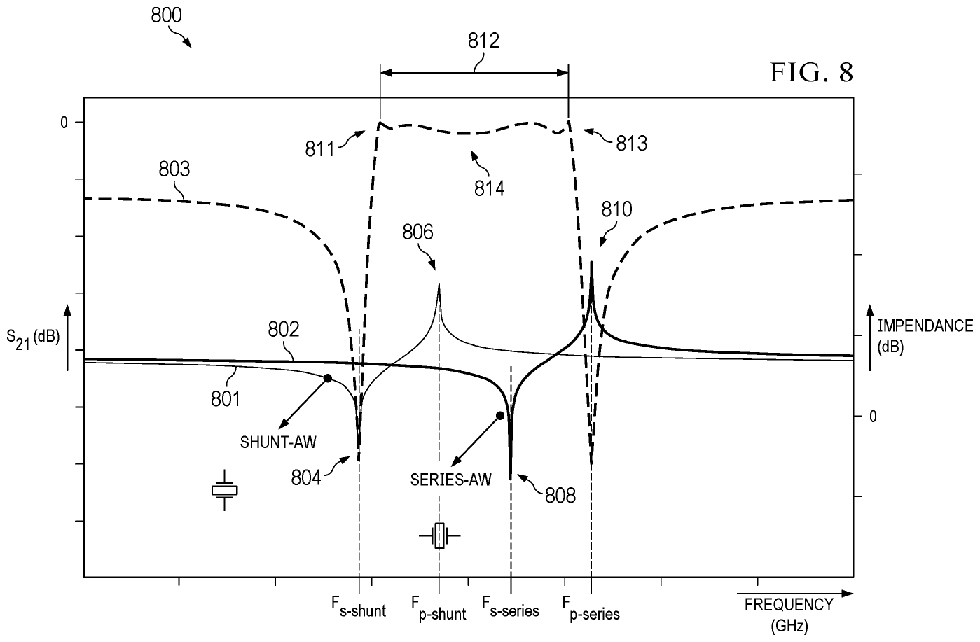

FIG. 7 is an impedance versus frequency graph 700 for an example EM resonator. The EM resonator in this example has a resonant frequency at fᵣₑₛ where the impedance peaks (at a value Zₚₑₐₖ). The impedance decreases (rolls off) as the frequency increases above or below the resonant frequency. At frequency below the resonant frequency, the overall impedance of the EM resonator can be dominated by inductor 601, and the impedance of inductor 601 reduces with signal frequency. The impedance of inductor 601 can approach zero for a DC signal. Also, at frequency above the resonant frequency, the overall impedance of the EM resonator can be dominated by capacitor 602, and the impedance of capacitor 602 also reduces as signal frequency increases. Capacitor 602 can become an AC short as the signal frequency approaches infinity.

FIG. 8 includes plots that represent examples of frequency responses of shunt and series AW resonators of filter 200 and the combined frequency response of the shunt and series AW resonators. FIG. 8 includes a graph 800 including plots 801, 802, and 803. Plot 801 represents an example impedance variation of shunt AW resonators (e.g., shunt AW resonators 218 and 222 in FIG. 2) with frequency. Plot 802 represents an example impedance variation of series AW resonators (e.g., series AW resonators 210 and 214 in FIG. 2) with frequency. Plot 803 represents an example of the combined frequency response (e.g., s21 or gain) of the shunt and series AW resonators. The left axis represents s21 parameter, and the right axis represents the impedance.

Referring to FIG. 8, the shunt AW resonators can have a series resonant frequency Fₛ₋ₛₕᵤₙₜ (also labelled 804) and a parallel resonant frequency Fₚ₋ₛₕᵤₙₜ (labelled 806). The series AW resonators can have a series resonant frequency Fₛ₋ₛₑᵣᵢₑₛ (labelled 808) and a parallel resonant frequency Fₚ₋ₛₑᵣᵢₑₛ (labelled 810). As described above, shunt AW resonators 218 and 222 can provide a transmission zero for the AW resonator filter at Fₛ₋ₛₕᵤₙₜ, and series AW resonators 210 and 214 can provide a transmission zero at Fₚ₋ₛₑᵣᵢₑₛ. Also, shunt AW resonators 218 and 222 can set a lower pole frequency, which sets the lower corner frequency 811 of pass band 812, and series AW resonators 210 and 214 can set an upper pole frequency, which sets the upper corner frequency 813 of pass band 812. The resonant frequencies of the series and shunt AW resonators can be determined from filter synthesis (e.g., based on a target pass band and a target out-of-band rejection) followed by poles/zeros extraction.

Also, the pass band transmission coefficient of the AW resonator filter within pass band 812 is at around 0 dB and can be defined by the impedances of shunt AW resonators and series AW resonators. The pass band gain can peak at the parallel resonant frequency of the shunt AW resonator (Fₚ₋ₛₕᵤₙₜ) at which the impedance peaks, and the portion of signal shunted to ground is at a minimum. The pass band gain can also peak at the series resonant frequency of the series AW resonator (Fₛ₋ₛₑᵣᵢₑₛ) at which the admittance peaks, and the impedance between the filter input and output can be close to zero. But the pass band transmission coefficient experiences a dip (pass band dip) 814 at a middle frequency between the Fₚ₋ₛₕᵤₙₜ and Fₛ₋ₛₑᵣᵢₑₛ frequencies. Specifically, the gain of the AW resonator filter peaks at around the Fₛ₋ₛₕᵤₙₜ and Fₚ₋ₛₑᵣᵢₑₛ frequencies. At frequency higher than Fₛ₋ₛₕᵤₙₜ, the gain of the AW resonator filter may dip due to the rapid impedance reduction of the shunt AW resonators starting at Fₚ₋ₛₕᵤₙₜ, which shunts more of the signal at the filter input to ground and reduces the pass band transmission coefficient, while the impedance of series AW resonators remain high. The impedance of the series AW resonators (and between the filter input and output) reduces as the frequency approaches Fₛ₋ₛₑᵣᵢₑₛ, where the series AW resonators can bring the filter transmission coefficient (s21) back up. The amount of the pass band dip can depend on the separation between frequencies 806 and 808, where a large separation can lead to a large dip and vice versa.

For many applications, such as the application shown in FIG. 1, it may be desirable to implement a bandpass filter with a larger fractional bandwidth. However, the large fractional bandwidth can increase the dip in the pass band gain. Specifically, to achieve a larger fractional bandwidth, the series resonant frequency 804 (Fₛ₋ₛₕᵤₙₜ) may be pushed to the left towards lower frequencies to reduce the lower corner frequency 811. If the kₜ² of the shunt AW resonators remain the same, the parallel resonant frequency 802 (Fₚ₋ₛₕᵤₙₜ) may also be pushed to the left by the same amount. Also, the series resonant frequency 808 (Fₛ₋ₛₑᵣᵢₑₛ) of the series AW resonators may be pushed to the right towards higher frequencies to increase the upper corner frequency 813. If the kₜ² of the series AW resonators remain the same, the shunt resonant frequency 810 (Fₚ₋ₛₑᵣᵢₑₛ) may also be pushed to right by the same amount. Such arrangements, however, can increase the frequency separation between the shunt resonant frequency 806 and series resonant frequency 808 at which the pass band gain peaks. Accordingly, the impedance of the shunt AW resonators (and the pass band gain) can reduce to an even lower value before the impedance of the series AW resonators start decreasing to bring up the pass band gain, which increases the in the pass band gain.

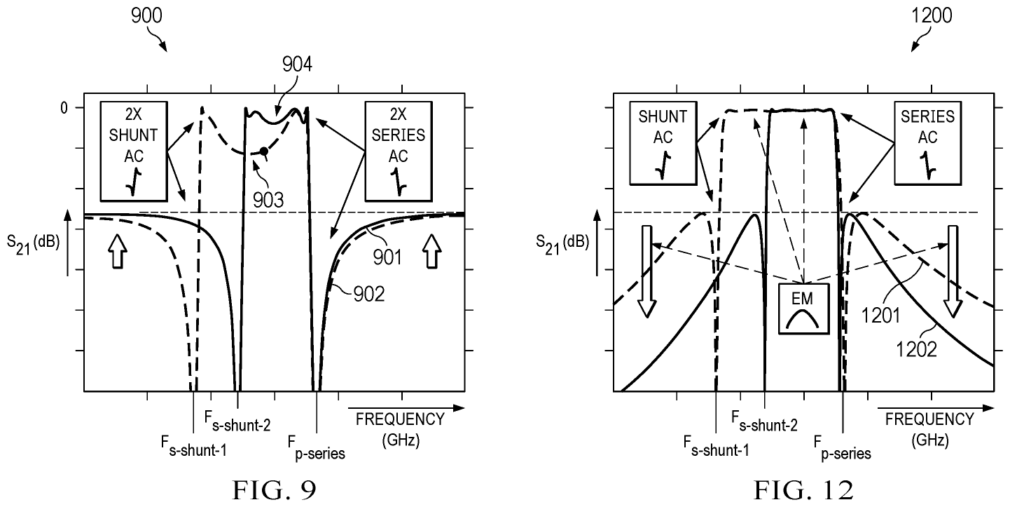

The effect of fractional bandwidth on the pass band dip is illustrated in FIG. 9. FIG. 9 includes a graph 900 including plots 901 and 902 of the frequency responses of a fourth-order AW resonator filter including the shunt and AW resonators of filter 200. The fractional bandwidth of the filter in plot 901 is wider than in plot 902 due to the series resonant frequency of the shunt AW resonator in plot 901 (Fₛ₋ₛₕᵤₙₜ₋₁) being pushed to the left versus in plot 902 (Fₛ₋ₛₕᵤₙₜ₋₂), while the parallel resonant frequency of the series AW resonator stays the same in plots 901 and 902 (Fₚ₋ₛₑᵣᵢₑₛ). But with such arrangements, the parallel resonant frequency of the shunt AW resonator becomes more separated from the series resonant frequency of the series AW resonator in plot 901 than in plot 902, which results in a much larger pass band dip 903 in plot 901 than then pass band dip 904 in plot 902.

Referring again to FIG. 8, in addition to the non-uniform pass band gain, the AW resonators also provide limited out-of-band rejection. This can be due to lack of mechanisms to reduce the filter transmission coefficient within the first stop band before the series resonant frequency 804 (the first transmission zero) and within the second stop band after the shunt resonant frequency 810 (the second transmission zero). Specifically, within the first and second stop bands, the impedances of the shunt and series AW resonators can stay relatively constant and above 0 dB. The series AW resonators do not completely disconnect the filter input from the filter output. The shunt AW resonators also do not completely shunt the signal to ground. Accordingly, within the first and second stop bands, the transmission coefficient of the AW resonator filter can remain relatively high, which leads to limited out-of-band rejection.

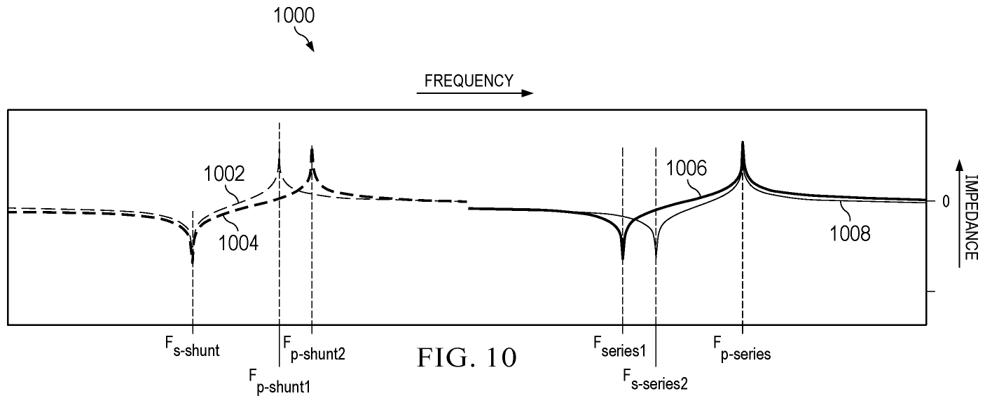

One way to reduce the pass band dip is by further separating out the series and parallel resonant frequencies of one of the shunt AW resonators and one of the series AW resonators to introduce additional peak impedance (for shunt AW resonator) and peak admittance (for series AW resonator), both of which can lift the gain. FIG. 10 illustrates an example of such arrangements. FIG. 10 includes graph 1000, which includes a plot 1002 of example impedance response of shunt AW resonator 218, a plot 1004 of example impedance response of shunt AW resonator 222, a plot 1006 of example impedance response of series AW resonator 210, and a plot 1008 of example impedance response of series AW resonator 214. Referring to FIG. 10, shunt AW resonators 218 and 222 can have same series resonant frequency Fₛ₋ₛₕᵤₙₜ but different parallel resonant frequencies Fₚ₋ₛₕᵤₙₜ₋₁ and Fₚ₋ₛₕᵤₙₜ₋₂. Also, series AW resonators 210 and 214 can have same parallel resonant frequency Fₚ₋ₛₑᵣᵢₑₛ but different series resonant frequencies Fₛ₋ₛₑᵣᵢₑₛ₁ and Fₛ₋ₛₑᵣᵢₑₛ₂. The AW resonator portion of filter 200 can have gain peaks at Fₚ₋ₛₕᵤₙₜ₋₂ and Fₛ₋ₛₑᵣᵢₑₛ₁. As the separation between Fₚ₋ₛₕᵤₙₜ₋₂ and Fₛ₋ₛₑᵣᵢₑₛ₁ reduces, the gain dip also can also reduce. However, such arrangements can lead to filter 200 having AW resonators having different kₜ². As explained above, this may require the AW resonators having different piezoelectric materials, which can increase complexity in the fabrication of the filter. Also, some of the AW resonators may need to have a large kₜ² to separate out the parallel and series resonant frequencies, and such a large kₜ² can be difficult or even impractical to implement.

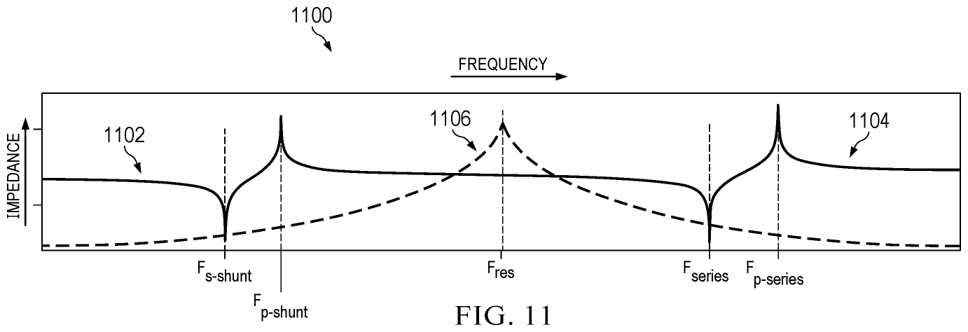

Referring again to FIG. 2 and FIG. 6, by having EM resonator network 226 in the middle of filter 200 with series AW resonator 210 and shunt AW resonator 218 on one side and series AW resonator 214 and shunt AW resonator 222 on the other side, non-uniform pass band gain can be mitigated, while the out-of-band rejection can be improved. FIG. 11 and FIG. 12 illustrate examples of using EM resonator network 226 to improve the uniformity of pass band gain and out-of-band rejection. FIG. 11 includes a graph 1100, which includes a plot 1102 of example impedance response of shunt AW resonators 218 and 222 having series and parallel resonant frequencies Fₛ₋ₛₕᵤₙₜ and Fₚ₋ₛₕᵤₙₜ, a plot 1104 of example impedance response of shunt AW resonators 222 and 210 having series and parallel resonant frequencies Fₛ₋ₛₑᵣᵢₑₛ and Fₚ₋ₛₑᵣᵢₑₛ, and a plot 1106 of example impedance response of EM resonator network 226 including a single EM resonator 240 having a resonant frequency Fᵣₑₛ.

As shown in FIG. 11, EM resonator network 226 can be configured to have resonant frequency Fᵣₑₛ between Fₚ₋ₛₕᵤₙₜ and Fₛ₋ₛₑᵣᵢₑₛ (e.g., at the middle frequency). As described above, EM resonator 240 can be a shunt resonator, and the frequency of EM resonator 240 can peak at the resonant frequency Fᵣₑₛ. Such configuration can increase the impedance between the middle of filter 200 and ground, which can reduce the portion of pass band signal shunted to ground and lift the pass band gain, and the pass band dip can be reduced. Also, because by providing an additional gain peak in the pass band, there is no need to increase the kₜ² of the AW series and shunt resonators and to use AW resonators of different kₜ² as shown in FIG. 10. Accordingly, AW resonators having a same and low kₜ², and fabricated using a common/known piezoelectric material (e.g., AlN, ZnO, and CdS) can be used to implement the filter. All these can facilitate fabrication and integration of the AW resonators in filter 200.

Also, EM resonator network 226 can improve the out-of-band rejection of filter 200. Specifically, the impedance of the shunt EM resonator 240 decreases/rolls off at frequencies below and above the resonant frequency. Because of the impedance roll off, a larger portion of the filter signal in the stop bands can be shunted to ground, which increases the out-of-band rejection.

The effect of EM resonator network 226 on the performance of filter 200 is illustrated in FIG. 12. FIG. 12 includes a graph 1200 including plots 1201 and 1202 of the frequency responses of a fifth-order filter 200 including the shunt and AW resonators and EM resonator network 226. The fractional bandwidth of the filter in plot 1201 is same as in plot 901, and the fractional bandwidth of the filter in plot 1202 is the same as in plot 902. But the dips 903 and 904 in FIG. 9 are substantially reduced in plots 1201 and 1202. Moreover, EM resonator network 226 introduces additional roll-offs beyond the frequencies of transmission zeros at Fₛ₋ₛₕᵤₙₜ₋₁, Fₛ₋ₛₕᵤₙₜ₋₂, and Fₚ₋ₛₑᵣᵢₑₛ as shown in plots 1201 and 1202, and provide improved out-of-band rejection compared with plots 901 and 902.

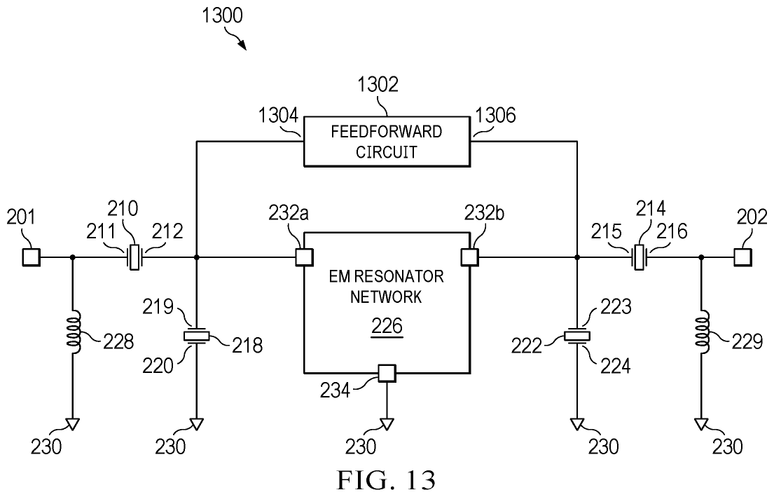

In some examples, a bandpass filter (e.g., filter 200) can also include a feedforward circuit coupled between the filter terminals. FIG. 13 is a schematic diagram of an example of bandpass filter 1300. Bandpass filter 1300 has the same components and ladder topology as filter 200, including shunt AW resonators 218 and 222, series AW resonators 210 and 214, EM resonator network 226, and inductors 228 and 229. Bandpass filter 1300 also includes a feedforward circuit 1302 having a terminal 1304 coupled to filter terminal 201 and a terminal 1306 coupled to filter terminal 202. The feedforward circuit can provide a phase-shifted version of the input signal (e.g., at terminal 201) to the output (e.g., terminal 202) to cancel (or at least attenuate) the filter output signal, which can create the effect of introducing additional transmission zeros, which can reduce the out-of-band rejection. Feedforward circuit 1302 can be implemented using an admittance inverter circuit and can be implemented on a same die (e.g., BAW die) as the AW resonators and the EM resonator network, so that filter 1300 can be implemented on a single die. In some examples, feedforward circuit 1302 can be implemented on a different die from the AW resonators and the EM resonator network.

The improvement in the out-of-band rejection by the additional transmission zeros provides room for trade-off of out-of-band rejection in return for reduced kₜ² or improved fractional bandwidth. Specifically, by reducing the kₜ² of the AW resonators, the original transmission zeros of the AW resonators become closer to pass band and weaken the out-of-band rejection at frequencies near the pass band. But the additional transmission zeros introduced by the feedforward circuit can increase the signal attenuation at those frequencies to maintain the overall out-of-band rejection. Accordingly, having the feedforward circuit can reduce the kₜ² requirement, which can facilitate fabrication and integration of AW resonators in the filter.

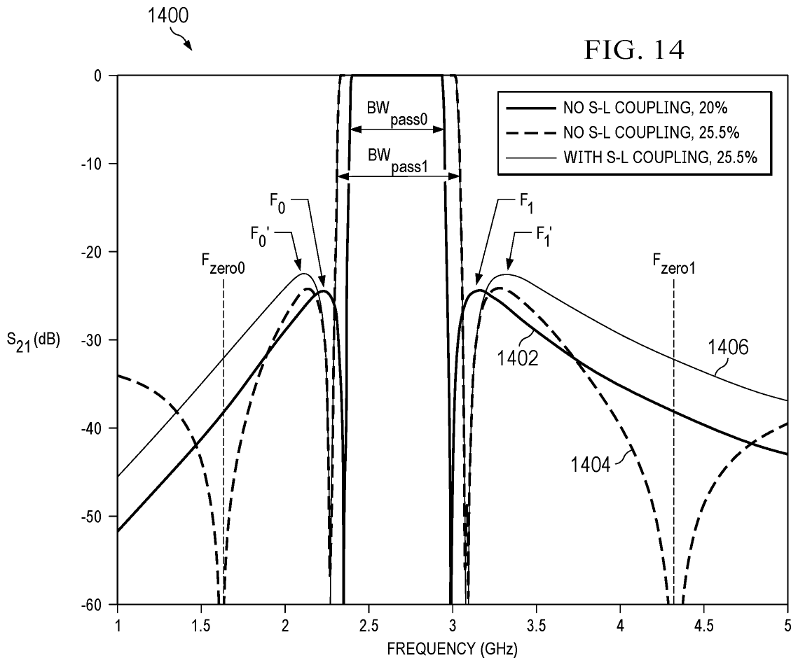

Also, the feedforward circuit allows increasing the fractional bandwidth while maintaining the out-of-band rejection. The improvement in fractional bandwidth is illustrated in FIG. 14. FIG. 14 includes a graph 1400 which includes a plot 1402, a plot 1404, and a plot 1406. Plot 1402 represents the frequency response (e.g., s21 parameter) of filter 200 without feedforward circuit 1302 and having a pass band BWₚₐₛₛ₀, which represents a fractional bandwidth of 20% Plot 1404 represents the frequency response of filter 200 also without feedforward circuit 1302 but having an enlarged pass band BWₚₐₛₛ₁ representing a fractional bandwidth of 25.5%. Plot 1406 represents the frequency response of filter 1300 having the enlarged pass-band BWₚₐₛₛ₁ (fractional bandwidth of 25.5%) The AW resonators of filters 200 and 1300 have the same kₜ².

Referring to plots 1402 and 1404, without the feedforward circuit 1302, filter 200 relies on EM resonator network 226 to provide the roll off of the frequency response on the left and right of the pass band. With pass band BWₚₐₛₛ₀, the roll off starts at frequencies F₀ (for plot 1402) and F₀′ (for plot 1404) on the left of the pass band, and starts at frequencies F₁ (for plot 1402) and F₁′ (for plot 1404) on the right of the pass band. Accordingly, the roll off starting frequency shifts left (F₀′ versus F₀) and right (F₁′ versus F₁) in plot 1404 versus plot 1402, and the out-of-band rejection of filter 200 degrades at frequencies below F₀′ and above F₁′ in plot 1404 compared with plot 1402.

With feedforward circuit 1302 (plot 1406), additional transmission zeros are introduced at frequencies F_{zero0} and F_{zero1}. The transmission zero frequency F_{zero0} is below F₀′, and the transmission zero frequency F_{zero1} is above F₁′. With such arrangements, feedforward circuit 1302 can provide additional attenuation to the signal at frequencies below F₀′ and above F₁′ on top of the roll off provided by EM resonator network 226. With the additional attenuation, the out-of-band rejection of filter 1300 in plot 1404 can be similar (or improved) compared with filter 200 in plot 1402, at least within the frequency ranges between F₀′ and F_{zero0} and between F₁′ and F_{zero1}, while the fractional bandwidth of filter 1300 increases by at least 20% compared with filter 200. A larger fractional bandwidth can be achieved by redesigning the response to have a larger return loss, which effectively reduces the required kₜ² for the resonators for BWₚₐₛₛ₀ and worsens the out-of-band rejection. The feedforward circuit 1302 improves the out-of-band rejection to lower the out-of-band ripple. Therefore, for BWₚₐₛₛ₁, the same kₜ² values with the same or better out-of-band rejection as in the case where the feedforward circuit was not present can be achieved.

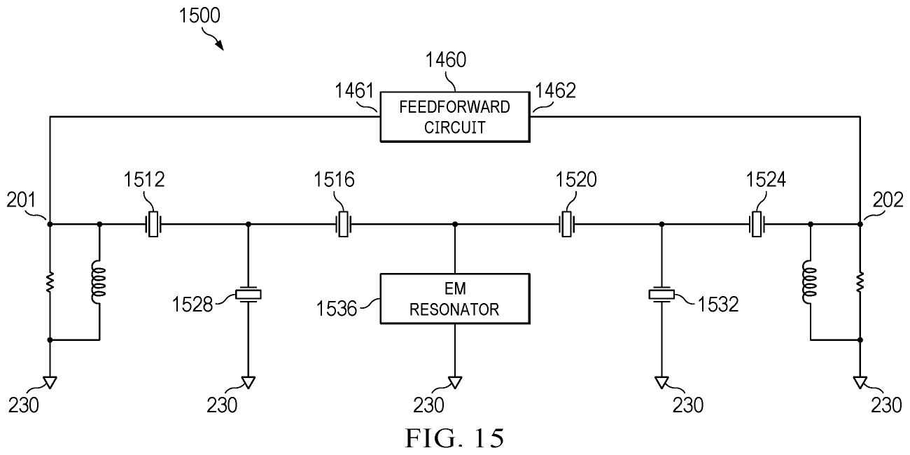

FIG. 15 is a schematic diagram of a 7^{th} order hybrid bandpass filter 1500. Hybrid bandpass filter 1700 can include series AW resonators 1512, 1516, 1520, and 1524 coupled in series between filter terminals 201 and 202, shunt AW resonators 1528 and 1532, EM resonator 1536, and feedforward circuit 1560. One terminal of series AW resonator 1512 is coupled to filter terminal 201, and one terminal of series AW resonator 1524 is coupled to filter terminal 202. Shunt AW resonator 1528 is coupled between series AW resonators 1512/1516 and the ground terminal 230. EM resonator 1536 is coupled between series AW resonators 1516/1520 and the ground terminal 230. Shunt AW resonator 1532 is coupled between series AW resonators 1520/1524 and the ground terminal 230.

As before, the shunt AW resonators 1528 and 1532 define the lower end of the filter's pass band frequency range, and the series AW resonators 1512, 1516, 1520, and 1524 define the upper end of the pass band frequency range. In the example of FIG. 15, EM resonator 1536 is in the middle of the ladder configuration of filter 1500 and functions to support the pass band (avoid or reduce midband dip) as described above. Feedforward circuit 1302 can be included between filter terminals 201 and 201 to improve the filter's out-of-band rejection, as described above.

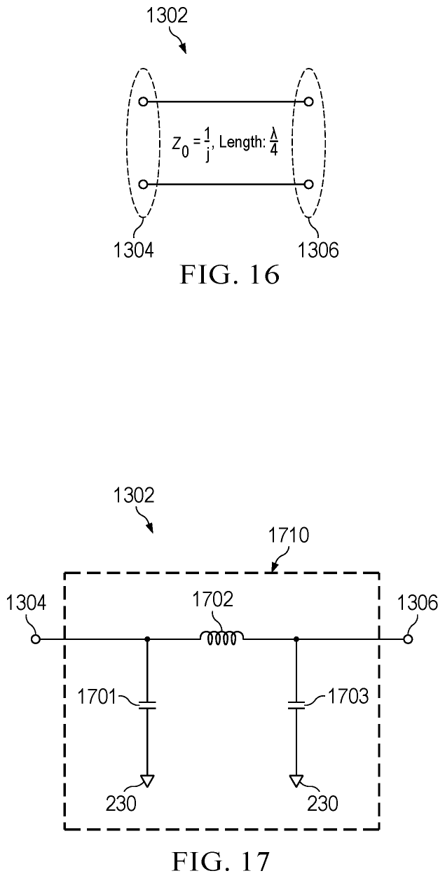

FIGS. 16-19 are schematic diagrams of examples of feedforward circuit 1302. Each example shown in FIGS. 16-19 can also be used to implement admittance inverter 250 of FIGS. 2B and 2C, but with different configurations. The feedforward circuit 1302 can be configured to (e.g., through filter synthesis and pole/zeros extraction) introduce transmission zeros at pre-determined frequencies, such as F_{zero0} and F_{zero1}, while the admittance inverter 250 of FIGS. 2B and 2C are configured as a quarter wavelength transmission line with the wavelength based on a particular signal frequency.

The example feedforward circuit 1302 of FIG. 16 is a quarter wavelength transmission line coupled between terminals 1304 and 1306. The wavelength can be set based on the target transmission zeros.

The example feedforward circuit 1302 of FIG. 17 includes a capacitor-inductor-capacitor network 1710. The capacitor-inductor-capacitor network 1710 includes a series inductor 1702 coupled between terminals 1304 and 1306 and shunt capacitors 1701 and 1703 coupled between terminals 1304 and 1306 and the ground terminal 230.

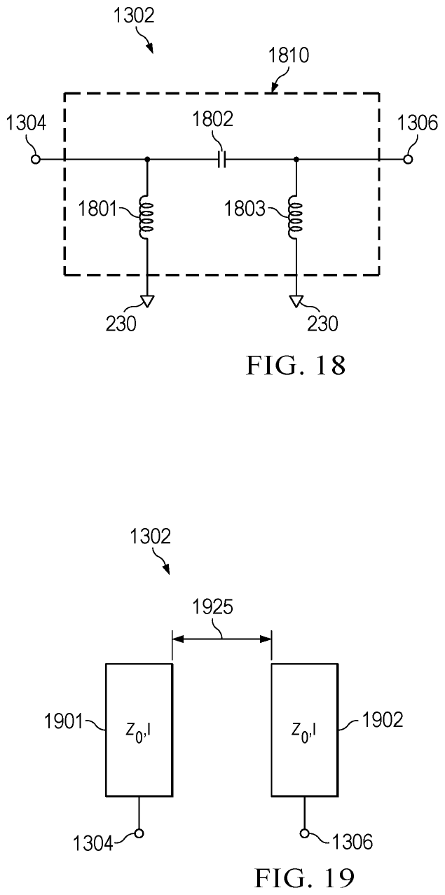

The example feedforward circuit 1302 of FIG. 18 includes an inductor-capacitor-inductor network 1810. The inductor-capacitor-inductor network 1810 includes a series capacitor 1802 coupled between terminals 1304 and 1306 and shunt inductors 1801 and 1803 coupled between terminals 1304 and 1306 and the ground terminal 230.

The example feedforward circuit 1302 of FIG. 19 includes first and second magnetically coupled transmission lines 1901 and 1902. The first transmission line 1901 is coupled to terminal 1304, and the second transmission line 1902 is coupled to the terminal 1306. The gap 1925 between the transmission lines 1901 and 1902 defines the magnetic coupling between the transmission lines, which in turn can set the transmission zeros.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as capacitors, unless otherwise stated, are generally representative of any one or more elements coupled in series and/or parallel to provide an amount of impedance represented by the capacitor shown. For example, a capacitor shown and described herein as a single component may instead be multiple capacitors, respectively, coupled in parallel between the same nodes. For example, a capacitor shown and described herein as a single component may instead be multiple capacitors, respectively, coupled in series between the same two nodes as the single capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A filter comprising:
an electromagnetic (EM) resonator network having a first EM terminal, a second EM terminal, and a third EM terminal, the third EM terminal coupled to a ground terminal;
a first acoustic wave (AW) resonator coupled between the first EM terminal and the ground terminal;
a second AW resonator coupled between the second EM terminal and the ground terminal;
a third AW resonator coupled between a first filter terminal and the first EM terminal; and
a fourth AW resonator coupled between a second filter terminal and the second EM terminal.

2. The filter of claim 1, wherein the EM resonator network includes:
an EM resonator having first and second EM resonator terminals, the second EM resonator terminal coupled to the third EM terminal;
a first admittance inverter coupled between the first EM terminal and the first EM resonator terminal; and
a second admittance inverter coupled between the second EM terminal and the first EM resonator terminal.

3. The filter of claim 1, wherein the EM resonator network includes:
a first EM resonator having first and second EM resonator terminals, the second EM resonator terminal coupled to the third EM terminal;
a second EM resonator having third and fourth EM resonator terminals, the forth EM resonator terminal coupled to the third EM terminal;
a first admittance inverter coupled between the first filter terminal and the first EM resonator terminal;
a second admittance inverter coupled between the first and third EM resonator terminals; and
a third admittance inverter coupled between the third EM resonator terminal and the second filter terminal.

4. The filter of claim 1, wherein the filter is configured as a bandpass filter having a pass band;
wherein the first and second AW resonators are configured to have first resonant frequencies that set a lower end of the pass band, the third and fourth AW resonators are configured to have second resonant frequencies that set an upper end of the pass band, and the EM resonator network is configured to have a third resonant frequency between the lower and upper ends of the pass band.

5. The filter of claim 1, wherein each of the first, second, third, and fourth AW resonators has a respective electromechanical coupling coefficient below 10%.

6. The filter of claim 5, wherein the first, second, third, and fourth AW resonators has an identical electromechanical coupling coefficient.

7. The filter of claim 5, wherein the first, second, third, and fourth AW resonators includes an identical piezoelectric material.

8. The filter of claim 5, wherein the first, second, third, and fourth AW resonators are implemented on a single die.

9. The filter of claim 5, wherein each of the first, second, third, and fourth AW resonators includes a respective piezoelectric material.

10. The filter of claim 9, wherein the piezoelectric material includes at least one of: Aluminum Nitride (AlN), Zinc Oxide (ZnO), or Cadmium sulfide (CdS).

11. The filter of claim 1, further including a feedforward circuit coupled between the first and second filter terminals.

12. The filter of claim 11, wherein the feedforward circuit is configured to introduce one or more transmission zeros at pre-determined frequencies between the first and second filter terminals.

13. The filter of claim 12, wherein the feedforward circuit has a first terminal and a second terminal, the first terminal coupled to the first filter terminal, the second terminal coupled to the second filter terminal, and the feedforward circuit includes at least one of:
a quarter wavelength transmission line coupled between the first and second terminals;
a capacitor-inductor-capacitor network including a series inductor coupled between the first and second terminals and shunt capacitors coupled between the first and second terminals and the ground terminal;
an inductor-capacitor-inductor network including a series capacitor coupled between the first and second terminals and shunt inductors coupled between the first and second terminals and the ground terminal; or
first and second transmission lines, the first transmission line magnetically coupled to the first terminal, and the second transmission line coupled to the second terminal.

14. The filter of claim 1, wherein the filter has a fractional bandwidth of at least 25%.

15. The filter of claim 1, wherein each of the first, second, third, and fourth AW resonators includes a respective bulk acoustic wave (BAW) resonator.

16. A filter comprising:
A first acoustic wave (AW) resonator, a second AW resonator, a third AW resonator, a fourth AW resonator, and an electromagnetic (EM) resonator network coupled between a first filter terminal and a second filter terminal; and
a feedforward circuit coupled between the first filter terminal and the second filter terminal.

17. The filter of claim 16, wherein:
the electromagnetic (EM) resonator network has a first EM terminal, a second EM terminal, and a third EM terminal, the third EM terminal coupled to a ground terminal;
the first acoustic wave (AW) resonator is coupled between the first EM terminal and the ground terminal;
the second AW resonator is coupled between the second EM terminal and the ground terminal;
the third AW resonator is coupled between the first filter terminal and the first EM terminal; and
the fourth AW resonator is coupled between the second filter terminal and the second EM terminal.

18. The filter of claim 17, wherein the EM resonator network includes:
an EM resonator having first and second EM resonator terminals, the second EM resonator terminal coupled to the third EM terminal;
a first admittance inverter coupled between the first EM terminal and the first EM resonator terminal; and
a second admittance inverter coupled between the second EM terminal and the first EM resonator terminal.

19. The filter of claim 17, wherein the EM resonator network includes:
a first EM resonator having first and second EM resonator terminals, the second EM resonator terminal coupled to the third EM terminal;
a second EM resonator having third and fourth EM resonator terminals, the forth EM resonator terminal coupled to the third EM terminal;
a first admittance inverter coupled between the first filter terminal and the first EM resonator terminal;
a second admittance inverter coupled between the first and third EM resonator terminals; and
a third admittance inverter coupled between the third EM resonator terminal and the second filter terminal.

20. The filter of claim 17, wherein the feedforward circuit is configured to introduce one or more transmission zeros at pre-determined frequencies between the first and second filter terminals.

21. The filter of claim 17, wherein the feedforward circuit has a first terminal and a second terminal, the first terminal coupled to the first filter terminal, the second terminal coupled to the second filter terminal, and the feedforward circuit includes at least one of:
a quarter wavelength transmission line coupled between the first and second terminals;
a capacitor-inductor-capacitor network including a series inductor coupled between the first and second terminals and shunt capacitors coupled between the first and second terminals and the ground terminal;
an inductor-capacitor-inductor network including a series capacitor coupled between the first and second terminals and shunt inductors coupled between the first and second terminals and the ground terminal; or
first and second transmission lines, the first transmission line magnetically coupled to the first terminal, and the second transmission line coupled to the second terminal.
